(19) United States
(12) Patent Application Publication
(10) Pub. No.: US 2009/0001384 A1
(43) Pub. Date: Jan. 1, 2009

(54) Group III Nitride semiconductor HFET and method for producing the same

(75) Inventors: Masayoshi Kosaki, Aichi-ken (JP); Yuhei Ikemoto, Aichi-ken (JP); Takahiro Sonoyama, Aichi-ken (JP); Hiroshi Miwa, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD., Aichi-ken (JP)

(21) Appl. No.: 12/213,882

(22) Filed: Jun. 25, 2008

(30) Foreign Application Priority Data
Jun. 27, 2007 (JP) 2007-169750

(51) Int. Cl. H01L 29/778; H01L 21/388

(52) U.S. Cl. 257/77; 438/172; 257/E21.403; 257/E29.246

(57) ABSTRACT

Provided is an HFET exhibiting reduced buffer leakage current. The HFET of the present invention includes an SiC substrate, an AlN layer, a graded AlGaN layer, a GaN layer, an AlGaN layer (Al compositional proportion: 20%), a source electrode, a gate electrode, and a drain electrode, wherein the AlN layer, the graded AlGaN layer, the GaN layer, and the AlGaN (Al: 20%) layer are successively stacked on the substrate, and the electrodes are formed on the AlGaN (Al: 20%) layer so as to be separated from one another. In the graded AlGaN layer, the Al compositional proportion gradually decreases from 30% (at the side facing the AlN layer) to 5% (at the side facing the GaN layer). Provision of the graded AlGaN layer reduces strain between the AlN layer and the GaN layer. Therefore, the HFET exhibits reduced buffer leakage current.

### BACKGROUND OF THE INVENTION

1. Field of the Invention

The present invention relates to a heterostructure field effect transistor (HFET) employing a Group III nitride semiconductor (hereinafter may be referred to as a “Group III nitride semiconductor HFET”).

2. Background Art

By virtue of their characteristics, Group III nitride semiconductors are promising materials for producing high-frequency semiconductor devices or power devices. Hitherto, research and development have been actively conducted on devices (e.g., HFETs) formed of Group III nitride semiconductors. For example, Japanese Patent Application Laid-Open (kokai) No. 2001-196575 discloses a Group III nitride semiconductor HFET.

FIG. 4 shows the configuration of a conventional Group III nitride semiconductor HFET 100. The HFET 100 includes an SiC substrate 101, an AlN layer 102, a GaN layer 103, an AlGaN layer 104, a source electrode 105, a gate electrode 106, and a drain electrode 107, wherein the layers 102, 103, and 104 are successively stacked on the substrate 101, and the electrodes 105, 106, and 107 are formed on the AlGaN layer 104 such that the electrodes are separated from one another. The HFET 100 is a normally-on HFET, in which a portion of the GaN layer 103 at the junction interface between the GaN layer 103 and the AlGaN layer 104 serves as a channel 108. In the HFET 100, source-drain current is controlled by applying negative voltage to the gate electrode 106.

Meanwhile, Japanese Patent Application Laid-Open (kokai) No. 2001-230447 discloses a technique for reducing lattice constant mismatch between a substrate and a GaN layer. According to the technique disclosed in this patent document, there is formed, between a substrate and a GaN layer, an AlGaN layer in which the Al compositional proportion gradually decreases from the side facing the substrate to the side facing the GaN layer, so that the lattice constant of the AlGaN layer is gradually changed to thereby reduce lattice constant mismatch between the substrate and the GaN layer.

In the aforementioned HFET 100 having a conventional configuration, even when voltage is applied to the gate electrode so as to achieve pinch-off, electric current flows between the source electrode and the drain electrode as drain voltage increases. Conceivably, this phenomenon results from generation of carriers attributed to crystal defects or an electric field caused by strain, which strain occurs at the junction interface between the AlN layer and the GaN layer due to the difference in lattice constant between the layers.

The technique disclosed in Japanese Patent Application Laid-Open (kokai) No. 2001-230447 is for the purpose of improving crystallinity of a layer formed on a buffer layer by changing, in a continuous or stepwise manner, the Al compositional proportion of the buffer layer when the buffer layer is formed on a substrate. This patent document does not suggest that the disclosed technique can reduce leakage current in an HFET during pinch-off.

### SUMMARY OF THE INVENTION

In view of the foregoing, an object of the present invention is to realize a Group III nitride semiconductor HFET having such a configuration that reduces source-drain current (buffer leakage current) during pinch-off.

In a first aspect of the present invention, there is provided a Group III nitride semiconductor HFET comprising a substrate; a first layer formed of AlN which is provided on the substrate; a second layer formed of GaN and provided by the intervention of the first layer; and a third layer which is provided on the second layer, the third layer joined to the second layer and serving as a barrier layer, wherein the HFET has a fourth layer formed of AlₓGa₁₋ₓN (0≦x≦1) which is provided between the first layer and the second layer and which is joined to both the first and second layers, and the fourth layer has an Al compositional proportion which gradually decreases from the side facing the first layer to the side facing the second layer.

The third layer serving as a barrier layer may be made of AlGaN. The third layer may be an AlGaN single layer, or an AlGaN layer having an i-layer-n-layer-i-layer structure. The n-layer may be formed through Si doping and serves as a carrier supply layer. The third layer may have a multi-layer structure including an AlGaN layer and at least one of a GaN layer and an InGaN layer.

In the fourth layer, the Al compositional proportion may be changed in a stepwise manner, or may be changed proportionally or otherwise changed continuously and curvilinearly.

The substrate may be, for example, a sapphire substrate, an SiC substrate, or an Si substrate.

A second aspect of the present invention is drawn to a specific embodiment of the HFET as described in the first aspect, wherein, in the fourth layer, the Al compositional proportion gradually decreases from 100% to 0%.

A third aspect of the present invention is drawn to a specific embodiment of the HFET as described in the first or second aspect, wherein the substrate is an SiC substrate.

In a fourth aspect of the present invention, there is provided a method for producing a Group III nitride semiconductor HFET, comprising forming a first layer from AlN on a substrate through reduced-pressure MOCVD; forming a fourth layer from AlₓGa₁₋ₓN (0≦x≦1) on the first layer through atmospheric MOCVD so that the Al compositional proportion gradually decreases as the growth of the fourth layer; forming a second layer from GaN on the fourth layer through atmospheric MOCVD; and forming a third layer from AlGaN on the-second layer through atmospheric MOCVD.

The reason why the first layer is formed through reduced-pressure MOCVD is to increase the flow rate of a raw material gas, so as to reduce consumption of the raw material gas before the gas reaches a wafer, which consumption would otherwise be caused by high reactivity of Al.

A fifth aspect of the present invention is drawn to a specific embodiment of the method for producing an HFET as described in the fourth aspect, wherein the fourth layer is formed so that the Al compositional proportion gradually decreases from 100% to 0%.

A sixth aspect of the present invention is drawn to a specific embodiment of the method for producing an HFET as described in the fourth or fifth aspect, wherein the fourth layer is grown at 900 to 1,100° C.

When the fourth layer is grown at 900 to 1,100° C., the layer exhibits high crystallinity, which is preferred. More preferably, the fourth layer is grown at 950 to 1,050° C., much more preferably at 1,000 to 1,050° C.

A seventh aspect of the present invention is drawn to a specific embodiment of the method for producing an HFET as described in any of the fourth to sixth aspects, wherein the first layer is grown at 1,000 to 1,200° C.

When the first layer is grown at 1,000 to 1,200° C., the AlN layer exhibits high crystallinity, which is preferred. More preferably, the first layer is grown at 1,050 to 1,150° C., much more preferably at 1,100 to 1,150° C.

An eighth aspect of the present invention is drawn to a specific embodiment of the method for producing an HFET as described in any of the fourth to seventh aspects, wherein the substrate is an SiC substrate.

According to the first aspect of the present invention, since the fourth layer formed of AlₓGa₁₋ₓN is provided between the first layer formed of AlN and the second layer formed of GaN so that, in the fourth layer, the Al compositional proportion gradually decreases from the side facing the first layer to the side facing the second layer, the HFET exhibits reduced buffer leakage current. This is because, since the lattice constant of the fourth layer is gradually changed, lattice constant mismatch between the first and second layers is reduced, and thus strain is suppressed.

As described in the second aspect of the present invention, when the Al compositional proportion gradually decreases from 100% to 0% in the fourth layer, the fourth layer is formed of AlN at the surface bonding to the first layer and GaN at the surface bonding to the second layer, and thus strain is further suppressed. Therefore, buffer leakage current is further reduced.

As described in the third aspect of the present invention, the substrate may be an SiC substrate.

According to the fourth to eighth aspects of the present invention, an HFET exhibiting reduced buffer leakage current can be produced.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a cross-sectional view of the configuration of an HFET 10 according to a first embodiment;

FIG. 2 is a graph showing the relationship between source-drain voltage and buffer leakage current;

FIG. 3 is a cross-sectional view of the configuration of an HFET 20 according to another embodiment of the present invention; and

FIG. 4 is a cross-sectional view of the configuration of a conventional HFET 100.

### DETAILED DESCRIPTION OF PREFERRED EMBODIMENTS

Specific embodiments of the present invention will next be described with reference to the drawings. However, the present invention is not limited to the embodiments.

### First Embodiment

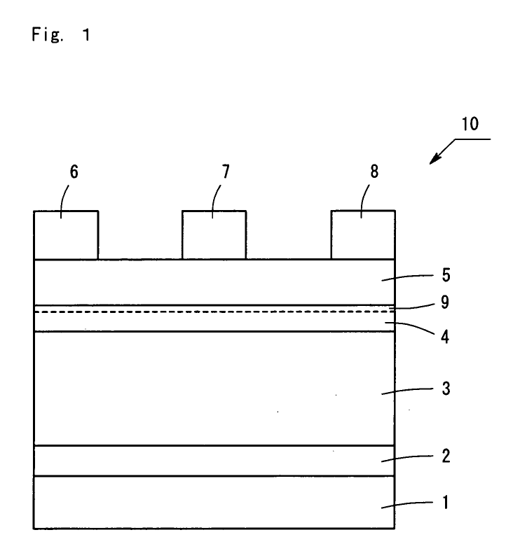

FIG. 1 is a cross-sectional view of the configuration of a Group III nitride semiconductor HFET 10 according to the first embodiment. The HFET 10 has an SiC substrate 1, an AlN layer 2 (first layer of the present invention), a graded AlGaN layer 3 (fourth layer of the present invention), a GaN layer 4 (second layer of the present invention), an AlGaN layer 5 (Al compositional proportion: 20%) serving as a barrier layer (third layer of the present invention), a source electrode 6, a gate electrode 7, and a drain electrode 8, wherein the layers 2, 3, 4, and 5 are successively stacked on the substrate 1, and the electrodes 6, 7, and 8 are formed on the AlGaN layer 5 so as to be separated from one another. In the graded AlGaN layer 3, the Al compositional proportion decreases in a stepwise manner from 30% (at the side facing the AlN layer 2) to 5% (at the side facing the GaN layer 4) in increments of 1%. None of the semiconductor layers are doped with an impurity.

The HFET 10 is a normally-on HFET, in which a portion of the GaN layer 4 at the junction interface between the GaN layer 4 and the AlGaN layer 5 serves as a channel 9.

The HFET of the first embodiment was produced as follows. Firstly, the AlN layer 2 (thickness: 200 nm) is grown on the SiC substrate 1 at 1,140° C. through reduced-pressure MOCVD. Subsequently, the graded AlGaN layer 3 (thickness: 1 μm) is grown on the AlN layer 2 at 1,000° C. through atmospheric MOCVD while the flow rate of trimethylaluminum (TMA) gas (i.e., a raw material gas for Al) is controlled so that the Al compositional proportion of the AlGaN layer 3 decreases in a stepwise manner from 30% to 5% in increments of 1%. Subsequently, the GaN layer 4 (thickness: 5 nm) is grown on the graded AlGaN layer 3 at 1,000° C. through atmospheric MOCVD. Thereafter, the AlGaN layer 5 (thickness: 45 nm) is grown on the GaN layer 4 at 1,000° C. through atmospheric MOCVD while the flow rate of TMA gas is controlled so that the AlGaN layer 5 has an Al compositional proportion of 20%. On the AlGaN layer 5, the source electrode 6, the gate electrode 7, and the drain electrode 8 are formed so as to be separated from one another.

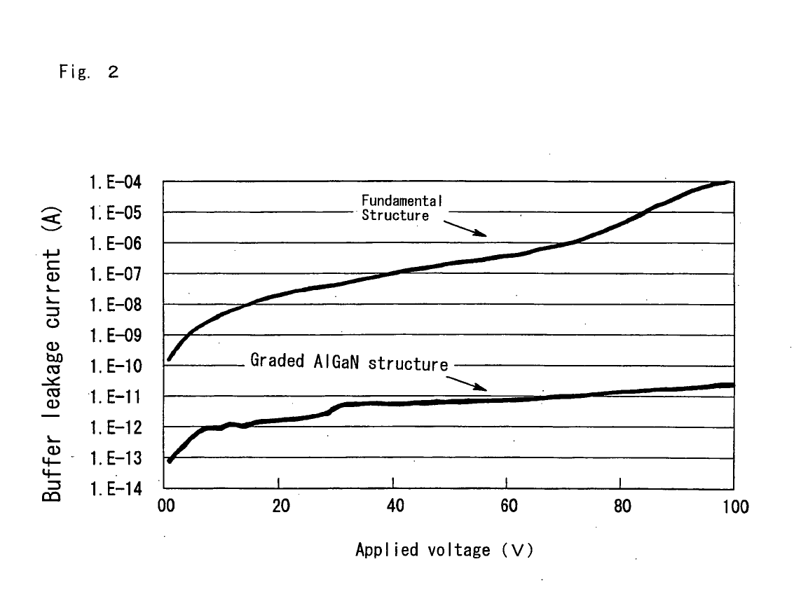

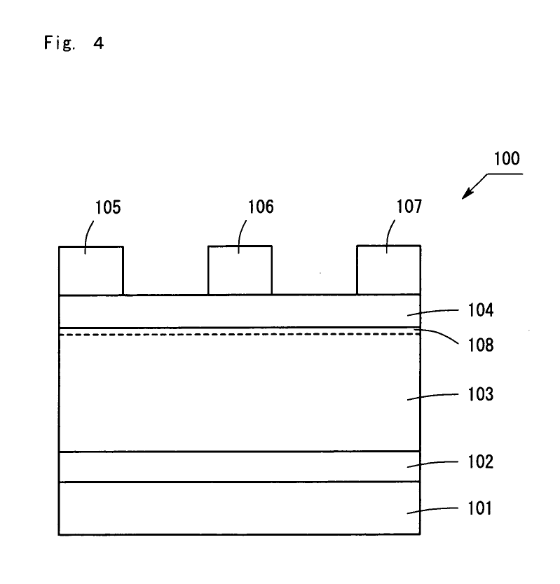

FIG. 2 is a graph showing buffer leakage currents, during pinch-off, of the HFET 10 of the first embodiment and the conventional HFET 100 shown in FIG. 4. The horizontal axis corresponds to source-drain voltage, whereas the vertical axis corresponds to buffer leakage current. In this graph, “Fundamental structure” corresponds to the HFET 100, and “Graded AlGaN structure” corresponds to the HFET 10.

The HFET 100 employed for comparison was produced as follows. Firstly, the AlN layer 102 (thickness: 200 nm) is grown on the SiC substrate 101 at 1,140° C. through reduced-pressure MOCVD, and then the GaN layer 103 (thickness: 1 μm) is grown on the AlN layer 102 at 1,000° C. through atmosphertic MOCVD. Subsequently, the AlGaN layer 104 is grown on the GaN layer 103, and the source electrode 105, the gate electrode 106, and the drain electrode 107 are formed on the AlGaN layer 104 so as to be separated from one another.

As is clear from the graph shown in FIG. 2, the buffer leakage current of the HFET 10 is about 1/10,000 to about 1/1,000,000 that of the HFET 100; i.e., the HFET of the present invention exhibits drastically reduced buffer leakage current. Conceivably, this effect is attributable to suppression of strain as a result of reduction of lattice constant mismatch between the AlN layer 2 and the GaN layer 4 through provision of the graded AlGaN layer 3 between the AlN layer 2 and the GaN layer 4.

In the first embodiment, the Al compositional proportion of the graded AlGaN layer 3 is changed in a stepwise manner. However, no particular limitation is imposed on the mode of change in Al compositional proportion, so long as the Al compositional proportion gradually decreases in the AlGaN layer 3 from the side facing the AlN layer 2 to the side facing the GaN layer 4. For example, the Al compositional proportion may be changed proportionally, or otherwise changed continuously and curvilinearly with respect to the thickness of the graded AlGaN layer 3.

In the first embodiment, the Al compositional proportion decreases from 30% to 5% in the graded AlGaN layer 3. When the Al compositional proportion decreases from 100% to 0% in the graded AlGaN layer 3, buffer leakage current can be further reduced. This is because, when the Al compositional proportion decreases from 100% to 0%, the graded AlGaN layer 3 has a composition of AlN at the surface bonding to the AlN layer 2 and a composition of GaN at the surface bonding to the GaN layer 4, and thus lattice constant mismatch between the AlN layer 2 and the GaN layer 4 is further reduced.

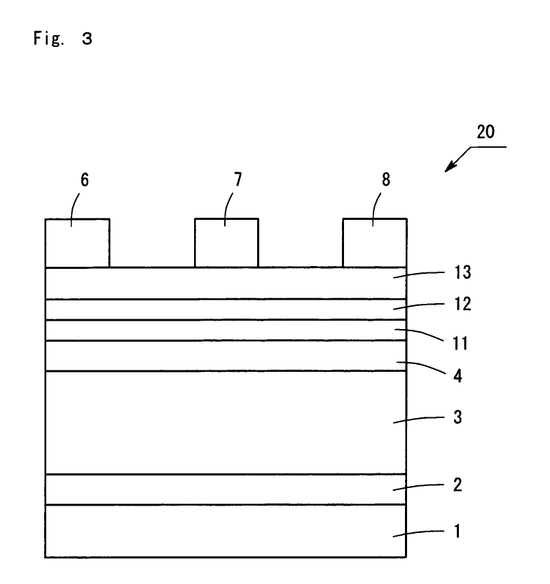

In the first embodiment, the barrier layer is an AlGaN single layer. However, the present invention is not limited to the configuration shown in FIG. 1. The HFET of the present invention, which exhibits reduced buffer leakage current, encompasses an HFET having the aforementioned fundamental configuration (i.e., the configuration in which the AlN layer 2, the graded AlGaN layer 3, and the GaN layer 4 are successively stacked on the substrate), and having, on the GaN layer 4, a conventionally known barrier layer structure. For example, the present invention encompasses an HFET 20 shown in FIG. 3. The HFET 20 has the same configuration as the HFET 10, except that the AlGaN layer 5 is substituted by a barrier layer having a three-layer structure including an AlGaN layer 11, an Si-doped n-AlGaN layer 12, and an AlGaN layer 13. This tri-layer structure can further increase carrier concentration, since the n-AlGaN layer 12 serves as a carrier supply layer. The AlGaN layer 5 of the HFET 10 may be substituted by a barrier layer having a structure in which an InGaN layer and an AlGaN layer are successively stacked on the GaN layer 4, or a structure in which a GaN layer and an AlGaN layer are successively stacked on the GaN layer 4.

In the first embodiment, an SiC substrate is employed. However, for example, a sapphire substrate or an Si substrate may be employed.

The HFET of the first embodiment is a normally-on HFET. However, the present invention can be applied to a normally-off HFET. For example, a normally-off HFET may be produced by, for example, reducing the thickness of the AlGaN layer 5 of the HFET 10.

The present invention can be applied to high-frequency devices or power devices.

What is claimed is:

1. A Group III nitride semiconductor HFET comprising a substrate; a first layer formed of AlN which is provided on the substrate; a second layer formed of GaN and provided by the intervention of the first layer; and a third layer which is provided on the second layer, the third layer joined to the second layer and serving as a barrier layer, wherein the HFET has a fourth layer formed of AlₓGa₁₋ₓN (0≦x≦1) which is provided between the first layer and the second layer and which is joined to both the first and second layers, and the fourth layer has an Al compositional proportion which gradually decreases from the side facing the first layer to the side facing the second layer.

2. An HFET as described in claim 1, wherein, in the fourth layer, the Al compositional proportion gradually decreases from 100% to 0%.

3. An HFET as described in claim 1, wherein the substrate is an SiC substrate.

4. An HFET as described in claim 2, wherein the substrate is an SiC substrate.

5. A method for producing a Group III nitride semiconductor HFET, comprising:
forming a first layer from AlN on a substrate through reduced-pressure MOCVD;
forming a fourth layer from AlₓGa₁₋ₓN (0≦x≦1) on the first layer through atmospheric MOCVD so that the Al compositional proportion gradually decreases as the growth of the fourth layer;
forming a second layer from GaN on the fourth layer through atmospheric MOCVD; and
forming, on the second layer, a third layer serving a barrier layer through atmospheric MOCVD.

6. A method for producing an HFET as described claim 5, wherein the fourth layer is formed so that the Al compositional proportion gradually decreases from 100% to 0%.

7. A method for producing an HFET as described in claim 5, wherein the fourth layer is grown at 900 to 1,100° C.

8. A method for producing an HFET as described in claim 6, wherein the fourth layer is grown at 900 to 1,100° C.

9. A method for producing an HFET as described in claim 5, wherein the first layer is grown at 1,000 to 1,200° C.

10. A method for producing an HFET as described in claim 6, wherein the first layer is grown at 1,000 to 1,200° C.

11. A method for producing an HFET as described in claim 7, wherein the first layer is grown at 1,000 to 1,200° C.

12. A method for producing an HFET as described in claim 8, wherein the first layer is grown at 1,000 to 1,200° C.

13. A method for producing an HFET as described in claim 5, wherein the substrate is an SiC substrate.

14. A method for producing an HFET as described in claim 6, wherein the substrate is an SiC substrate.

15. A method for producing an HFET as described in claim 7, wherein the substrate is an SiC substrate.

16. A method for producing an HFET as described in claim 8, wherein the substrate is an SiC substrate.

17. A method for producing an HFET as described in claim 12, wherein the substrate is an SiC substrate.
